(19) United States
(12) Patent Application Publication
(10) Pub. No.: US 2024/0421255 A1
(43) Pub. Date: Dec. 19, 2024

(54) METHOD FOR PROCESSING AN OPTOELECTRONIC COMPONENT AND OPTOELECTRONIC COMPONENT

(71) Applicant: ams-OSRAM International GmbH, Regensburg (DE)

(72) Inventor: Tansen Varghese, Regensburg (DE)

(21) Appl. No.: 18/703,624

(22) PCT Filed: Oct. 28, 2022
(86) PCT No.: PCT/EP2022/080287

§ 371 Date: Apr. 22, 2024

(30) Foreign Application Priority Data
Oct. 29, 2021 (DE) 10 2021 212 220.5

(51) Int. Cl. H01L 33/32; H01L 33/00; H01L 33/02; H01L 33/06; H01L 33/12

(52) U.S. Cl. CPC H01L 33/32; H01L 33/007; H01L 33/025; H01L 33/06; H01L 33/12

(57) ABSTRACT

In an embodiment a method for processing an optoelectronic component includes providing a growth substrate having a first lattice constant, epitaxially depositing a sacrificial layer based on GaN with a dopant concentration higher than 1e¹⁸ atoms/cm³ having a second lattice constant different from the first lattice constant, epitaxially depositing a top layer having a lower doping concentration than the sacrificial layer based on GaN having a third lattice constant different from the first lattice constant, wherein a growth of the sacrificial layer and the top layer generates a plurality of dislocations on a surface of the top layer, and electrochemically porosifying the sacrificial layer through the dislocations on the exposed first portions such that the sacrificial layer below the second portions is at least partially porosified and forming a functional layer stack onto the second portions based on an InGaN semiconductor material.

### CROSS-REFERENCE TO RELATED APPLICATIONS

This patent application is a national phase filing under section 371 of PCT/EP2022/080287, filed Oct. 28, 2022, which claims the priority of German patent application 10 2021 212 220.5, filed Oct. 29, 2021, each of which is incorporated herein by reference in its entirety.

### TECHNICAL FIELD

The invention concerns a method for processing an optoelectronic component having a semiconductor material in particular material including indium. The present invention also relates to an optoelectronic device.

### BACKGROUND

The processing of optoelectronic components based on the GaN material system comprises various challenges limiting the overall IQE and other relevant characteristics of such components. Partially these challenges are caused by the lattice mismatch between the growth substrate or carrier substrate and the subsequently deposited GaN based layers. The lattice mismatch causes an increased strain in the crystal structure of the grown material, which when exceeding certain limits result in crystal defects, dislocations and other effect.

The issue of lattice mismatch is exacerbated when going to longer and shorter wavelengths such as red or UV by adjusting the GaN base material with other elements. For example, for obtaining longer wavelength, Indium is added resulting in InGaN material. However, incorporating enough indium homogenously is difficult because the strain reduces the Indium incorporation. While several methods have been proposed, like for instance using lattice adjusted growth substrates, or with more exotic configurations such as nanorods, the incorporation of indium causing a shift to longer wavelength still proves a challenge.

### SUMMARY

It is known that strain reduction using one or more sacrificial layers prior to growing a functional layer stack may reduce the above mentioned issue. Such strain reduction can be achieved using electrochemical porosification providing an etchant to the sacrificial layer.

It has been found that it is sufficient to bring the etchant in contact with the surface of a top layer, which is not meant to be etched by the etchant during the porosification process. The etchant does, however, etch through dislocations in the top layer until it reaches the sacrificial layer, in which the porosification process mainly takes place. However, it was also found that holes are generated nonetheless by the etchant at the positions of such dislocations resulting in an uneven and degraded surface. In view of the dislocation density in the range of 1e8 per cm², the cavities or holes generated by the etchant on the top surface provide a challenge in creating a high quality surface on which to grow additional device layers. This also makes subsequent chip processing more difficult.

Embodiments provide an improved method processing an optoelectronic component that comprises a semiconductor material. The method comprises the step of providing a growth substrate having a first lattice constant. On said growth substrate a sacrificial layer is epitaxially deposited. These are based on GaN material. The sacrificial layer comprises a dopant concentration higher than about 1e18 atoms/cm³. The sacrificial layer comprises a second lattice constant different from the first lattice constant. As a result thereof, dislocations are induced in the sacrificial layer which extend through the layer in a random fashion. Then, a top layer based on GaN material having a lower doping concentration than the sacrificial layer is grown epitaxially. The top layer comprises a lower doping concentration than the sacrificial layer and may also have a third lattice constant different from the first lattice constant. The above mentioned dislocations may extend through the top layer till its surface.

In some instances of the proposed method, the sacrificial layer and the top layer may comprise the same material but with different doping concentrations. In particular, the top layer can be an undoped layer or a slightly doped layer that comprises a dopant concentration at least 10 times smaller than the dopant concentration of the sacrificial layer.

For the purpose of this application, the expression “based on GaN” material is to be understood that the respective layer contains GaN either in pure form, but also with unavoidable impurities. Likewise, when not explicitly excluded, a GaN based material may also include a ternary semiconductor material like AlGaN or InGaN with varying Al or In content, but also quaternary semiconductors like AlInGaN.

In a subsequent step, a structured mask is generated on the surface of the top layer, wherein first portions of the surface are exposed and second portions of the surface are covered. An etchant configured for electrochemical porosification of the sacrificial layer is provided and applied to the exposed regions and an electrochemical porosification conducted. The sacrificial layer is electrochemically porosified through the dislocations on the exposed portions, such that the sacrificial layer below the second portions are also at least partially porosified.

It has been found that the porosification process takes place not directly below the exposed surfaces but also laterally. In particular, the etchant will conduct a lateral porosification of the sacrificial layer below the covered portions as well. Such lateral porosification can extend several ten to hundred micrometres thus enabling the process to substantially porosify the sacrificial layer beneath the covered first portion.

Finally, the mask can be removed and a functional layer stack is formed onto the second portions. The functional layer stack is based on AlInGaN semiconductor material and comprises at least one active layer region. Due to the porosification process, the strain in the top layer and the functional layer stack is reduced and the crystal lattice stress relaxed. This will allow incorporating more Indium or Aluminium into the crystal lattice without lattice defects or induces additional strain. Furthermore, as the second portions were covered during the porosification process, the dislocation at the top layer's surface are not affected by the etchant. Rather, the surface can now be overgrown with an even material acting as high quality basis for the functional layer stack.

In some aspects it has been found that the electrochemical porosification through the dislocations on the exposed portions generates holes in the top layer, having a diameter between 10 nm and 200 nm and in particularly between 10 nm and 100 nm. The size of the holes may vary depending on the etchant.

In some instances, at least one of the etchant as well as the timing, temperature, voltage, current through the semiconductor material as well as the doping in the sacrificial layer are adjusted to set the porosification degree of the sacrificial layer. It is useful to maintain the porosification degree below 90% as the stability of the porosified layer decreases rendering handling of the wafer and the functional layer stack difficult. In some instances, the sacrificial layer comprises a porosification degree larger than 30% and in particular between 70% and 90%. In some instances, it may be in the range of 50% to 80%. Such porosification degrees provide a simpler lift-off in some instances, as the adhesion force exerted by the sacrificial layer is significantly reduced. In other instances, the sacrificial layer may be used as a contact, e.g. by applying metal contacts on top or further processing the layer after rebonding the structure.

The sacrificial layer is highly doped for example above about 1e18 atoms/cm³ and in particular in the range of 3e18 atoms/cm³ to 1e20 atoms/cm³. Generally, the sacrificial layer should either be highly doped or comprise a smaller bandgap than the top layer. This will ensure that the etchant will mainly etch or corrode the sacrificial layer and not the top layer throughout the porosification process. Likewise, the top layer may comprise a dopant concentration around 10 times lower than the dopant concentration in the sacrificial layer. In some instances, the top layer is an undoped layer.

The dopant may usually be of an n-type but can also be of a p-type in case growth is performed with a p-type sacrificial layer. Examples of possible dopants are Si and Ge, Se, Sn, C, Zn, Be or Mg which can be added during the epitaxial deposition steps. In some instances, the dopant concentration may be adjusted during the deposition of the sacrificial layer. A varying dopant concentration may support lateral porosification beneath the covered portions during the porosification step.

Some further aspects concern the step of providing a growth substrate. In some instances, a support carrier may be provided on which an initial buffer layer is deposited. The deposition may be conducted using epitaxy or any other suitable process. In some instances, the support carrier comprises a lattice constant different from the initial buffer layer thus inducing lattice mismatch and subsequently crystal defects and dislocations extending through the initial buffer layer. The initial buffer layer may include undoped GaN. The sacrificial layer is then deposited onto the initial buffer layer. Using the same base material e.g. GaN with different doping levels may be beneficial, both in term of growth speed and parameter control. The above-mentioned induced dislocations are usually randomly distributed across the surface. The average density of dislocations is in the range between 5e7 dislocations/cm² to 1e9 dislocations/cm² and in particular in the range between 8e7 dislocations/cm² and 6e8 dislocations/cm².

In some aspects, the structured mask covering the second portion on the top layers surface is a dielectric mask. In other aspects, it is an organic photo resist, which can withstand the porosification process. After removal of the structured mask, the functional layer stack is formed onto the second portions. For this purpose, one or more differently doped layers, e.g. an n-type doped layer and a p-type doped layer are deposited onto the second portions with the least one active layer region in between.

In some aspects, a dielectric layer is provided on the first portions. The dielectric mask will fill and cover the cavities and holes caused by the etchant due to the exposed dislocations. This step may be conducted prior to removing the structured mask. The dielectric mask can be covered with a photo resist or any other suitable material prior to depositing buffer layers or doped layers on the second portions. In some instances, a doped layer of AlInGaN based material is formed on the second portions. In some instances, the InGaN, InGaAIN, InGaAlP or InGaP semiconductor material in the functional layer stack may comprise an Indium content in the range between 0.0001% by mass to 25% by mass and in particular between 0.5% by mass to 20% by mass.

In some other aspects, the first portions are etched, e.g. by a wet etch process at least until the porosified sacrificial layer is reached. Alternatively, an anisotropic etching process may be used to ensure steep edges and steep side surfaces on the second portions. A dielectric insulating material, like for example SiO₂, covers the etched first portions. The etch will expose the second portions as protrusions, which can be subsequently processed after removing the structured mask. These steps can be done using the first structuring as the defining mask. Other steps such as polishing, and selective etching for lift-off can be utilized.

In some further aspects, the functional layer stack can be re-bonded to get access to the at least partially porosified sacrificial layer. As already indicated the remaining porosified layer can be removed or processed to provide a dedicated functionality.

In some further aspects, at least one active layer region comprises one or more quantum wells. To prevent further lattice mismatch and crystal defects adding to a non-radiative recombination, the lattice constant of the at least one active layer region deviates from a lattice constant of the top layer in a range between 0.5% and 5% and in particular between 0.5% and 3% or slightly less, e.g. 2.7%.

In some further aspects, the porous layer can either be removed completely during processing of the device, in case of a thin film device (bonded to a carrier and the substrate removed). Alternatively, it is left on the device, as a light scattering layer (both in thin film or non-thin film devices). Hence, the porous layer is not always a sacrificial layer.

Another aspect is related to an optoelectronic component. Said component comprises a growth substrate having an initial buffer layer, as well as a doped porosified sacrificial layer deposited on the initial buffer layer. In accordance with some aspects of the proposed principle, an undoped top layer comprising first portions and second portions is arranged on the doped porosified sacrificial layer. A functional layer stack based on InGaN semiconductor material is deposited onto the second portions, the functional layer stack comprising at least one active layer region. An optional dielectric mask is formed on the first portions of the top layer. The doped sacrificial layer is porosified below the first and second portions.

The optoelectronic component comprises in some aspects randomly located dislocations in the second portions of the top layer. The dislocations have an average density in the range between 5e7 dislocations/cm² to 1e9 dislocations/cm² and in particular in the range between 8e7 dislocations/cm² and 6e8 dislocations/cm². Furthermore, the doped sacrificial layer comprises a porosification degree larger than 30% and in particular between 70% and 90%. The doping concentration may be in the range larger than 1e18 atoms/cm³ and in particular may lie between 3e18 atoms/cm³ and 1e19 atoms/cm³. In some other aspects, the functional layer stack may comprise an Indium content in the range between 0.0001% by mass to 25% by mass and in particular between 0.5% by mass to 20% by mass.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 illustrates a schematic view of a semiconductor layer stack with dislocations illustrating some aspects of the proposed principle;

FIGS. 2A and B show the first two steps of a method for processing an optoelectronic component in accordance with some aspects of the proposed principle;

FIG. 3A to 3D illustrate the subsequent steps of a method for processing an optoelectronic component in accordance with some aspects of the proposed principle;

FIG. 4A to 4C illustrate some steps of a method for processing an optoelectronic component in accordance with some aspects of the proposed principle; and

FIG. 5A to 5C illustrate some steps of a method for processing an optoelectronic component in accordance with some aspects of the proposed principle.

### DETAILED DESCRIPTION OF ILLUSTRATIVE EMBODIMENTS

The following embodiments and examples disclose different aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the Figures can be combined with each other without further ado, without this contradicting the principle according to the invention. Some aspects show a regular structure or form. It should be noted that in practice slight differences and deviations from the ideal form or shape may occur without, however, contradicting the inventive idea.

In addition, the individual Figures and aspects are not necessarily shown in the correct size or dimensions, nor do the proportions between individual elements have to be essentially correct. Some aspects are highlighted by showing them enlarged. However, terms such as “above”, “above” “below”, “below” “larger”, “smaller” and the like are correctly represented with regard to the elements in the Figures. So it is possible to deduce such relations between the elements based on the Figures.

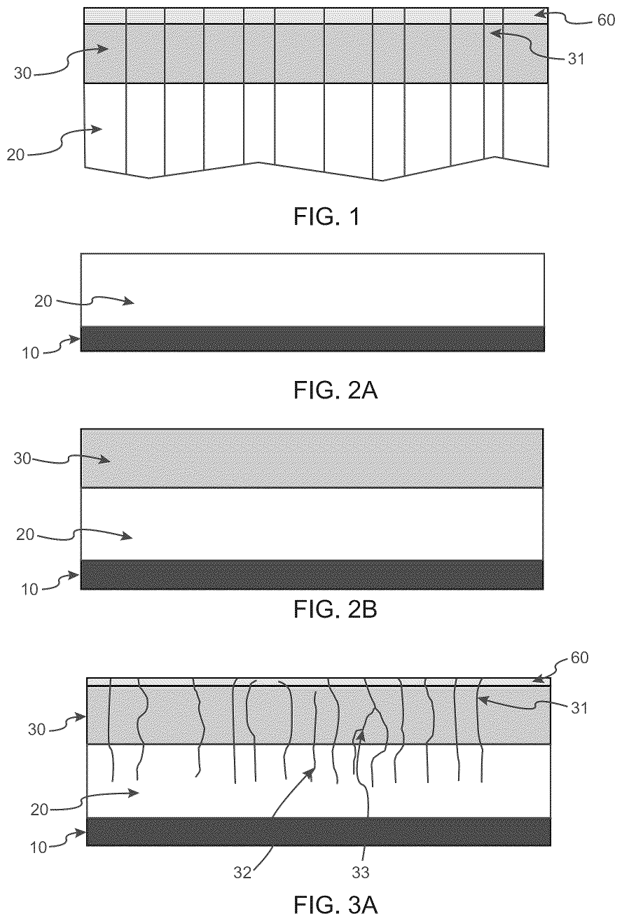

FIG. 1 illustrates a schematic view of a semiconductor layer stack with dislocations illustrating some aspects of the proposed principle.

The layer stack comprises of a plurality of different semiconductor layers 20, 30 and 60, which are based in this embodiment on the GaN material. It is however understood in the context of this application that different materials can be used for the respective layers including ternary and quaternary semiconductor material. Likewise, the material for the layer can be doped during their respective deposition.

Some of the semiconductor layers 20, 30 and 60 comprise a lattice constant, which is different from adjacent semiconductor layers. For example, a growth substrate (not illustrated in FIG. 1) may comprise a lattice constant, which is shorter than the lattice constant of a layer stack 20 deposited thereon. For example, the lattice constant of a sapphire growth substrate is usually in the range of 2.8 Angstrom while the respective lattice constant for GaN layer is larger and may be in the range larger than 3 Angstrom.

However, the various lattice constants may change depending on the respective crystal structure of the growth substrate and the subsequent buffer layers. Likewise, different orientations of the growth substrate may also change the overall lattice constant.

In accordance with the proposed principle, layer 20 deposited on the growth substrate comprises a lattice mismatch with respect to the growth substrate, thereby inducing strain in the deposited crystal structure of layer 20. As a result of that strain, dislocations and crystal defects 31 may occur in the deposited semiconductor material 20. The dislocations are generated during deposition and growth of layer 20 and are not always cured by overgrowing more semiconductor material. Rather, the dislocations caused by the lattice mismatch grow and extend when more material is added through the layer. They also continue to extend when the depositing material is changed, i.e. when a second layer 30 is deposited on top layer 20.

Secondly, layer 30 may comprise a different material with a different lattice constant. Alternatively, the same material can be used, but for example with different doping concentrations or different dopant. Likewise, layer 60 may comprise a different material and with different doping. In any case, the dislocations, as illustrated therein may extend through the different layers and might be visible or could be made visible even on the surface of top layer 60.

The dislocations 31 are randomly distributed along the surface of the top layer and may comprise a density in the range of 10e8 dislocations/cm². The density corresponds to about one dislocation/μm². As a result of those randomly localized dislocations, the epitaxial growth of further semiconductor layers including an active region to manufacture optoelectronic devices may be challenging. In addition, a change of the lattice constant for subsequently grown material may cause additional strain and therefore results in further dislocations in the top layer.

For example, such change in lattice constant occurs in Indium-based semiconductor systems, in which Indium is added to Gallium-Nitride, GaN, Gallium-Phosphide, GaP or Aluminum-Gallium-Nitride, AlGaN or Aluminum-Gallium-Phosphide, AlGaP to shift the band gap to lower energies and thus to more reddish wavelength.

Various solutions have been proposed to prevent such dislocations from hampering the growth of Indium containing layer with high quality. One of such solutions is utilizing a porosification of a so-called sacrificial layer beneath the top layer. It has been found that the porosification increases the extent of elastic expansion and contraction of the sacrificial layer, thereby relaxing the stress and strain induced by the different lattice constants. Hence, layers with different lattice constants (both smaller or larger than the lattice constant of the growth substrate or a buffer layer) can be grown without generating more dislocations due to the induced stress.

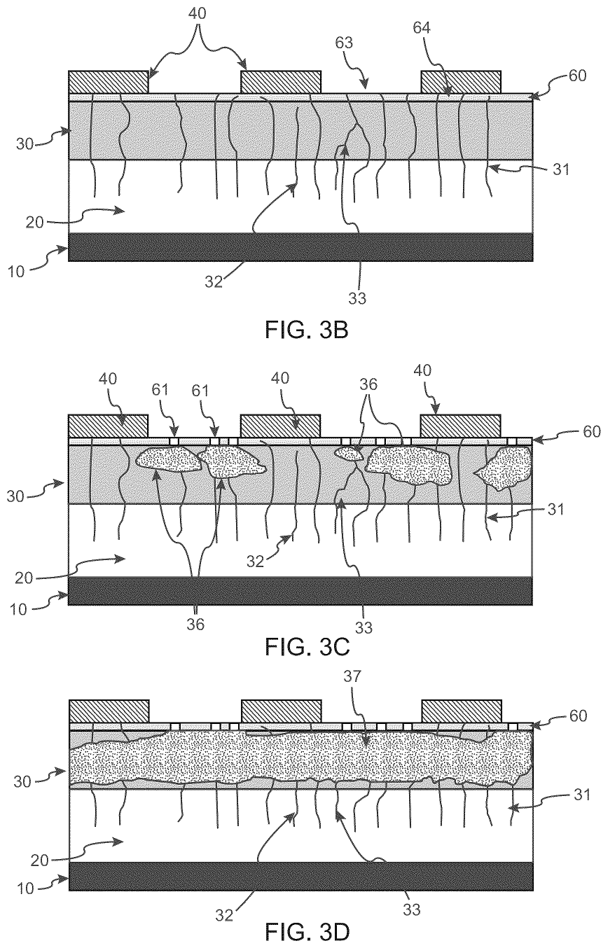

FIGS. 2A and 2B as well as FIG. 3A to 3D illustrate various method steps making use of a sacrificial porosification layer in accordance with some aspects of the proposed principle.

FIG. 2A illustrates the first step of a method for processing an optoelectronic device, in which an initial buffer layer 20 is deposited over a growth substrate 10. As previously explained, the growth substrate 10 comprises a lattice constant, which is different from the lattice constant of the initial buffer layer 20. As a result, the growth substrate crystal structure induces a strain in the initial buffer layer during epitaxial deposition of the initial buffer layer's material. When the strain reaches or exceeds a certain threshold, crystal defects are generated in the deposited material. The defects include but are not limited to line defects, point defects, volume defects and surface defects. The type of defect as well as its size is more or less randomly distributed, but can be biased to one or two types based on the growth orientation and other process parameters for example. The initial buffer layer 20 may comprise a thickness of several hundred nanometres to several micrometres in order to obtain a smooth and planar surface on a large scale.

A sacrificial layer 30 is deposited on top of the initial buffer layer 20. The sacrificial layer 30 and the initial buffer layer 20 comprise the same base material, for example GaN. Alternatively, Aluminum can replace some of the Gallium, forming the ternary material system AlGaN. In contrast to the initial buffer layer 20, the sacrificial layer 30 is highly doped such that it comprises a relatively low resistance and good conductivity. The doping during the position of the sacrificial layer is performed by adding dopant in the gas phase during growth. The doping can easily be changed without changing the base material system. Doping concentration of the sacrificial layer can be higher than around 1e18 atoms/cm³.

As a result of the different lattice structure between the growth substrate 10, the initial buffer layer 20 and the p-doped sacrificial layer 30, several dislocations take place in the initial buffer 20. These dislocations extend through the sacrificial layer 30 and a top and undoped layer 60 also made of the same material system as the p-doped sacrificial layer 30.

FIG. 3A illustrates a schematic view of a layer stack processed in this way. The layer stack according to FIG. 3A comprises various dislocations, 31, 32 and 33, extending from the initial buffer layer 20 through the sacrificial layer 30 and the top layer 60. Particularly some dislocations marked with reference 31 extend through the various layers to the surface of top layer 60. The dislocations form crystal defects and other deformations, which are useful for the subsequent steps further outlined in detail below.

Other dislocations 32 may extend through various layers. For example, dislocations 32 have their starting point in initial layer 20 and extend through the sacrificial layer 30, but can actually be overgrown, as indicated. As a result, those dislocations 32 may not reach the surface of the top layer 60. Further dislocations 33 are either branching off from existing line or point defects or, as in the present example, merge with different defects and dislocations extending through the layers. The branching off as well as the merger of dislocations can take place in the sacrificial layer 30 but also in the initial layer 20, and in some rare occurrences also in the top layer 60. Top layer 60 can have a thickness up to around one hundred nanometres, and includes a significantly lower doping level in comparison to sacrificial layer 30. In the present embodiment, layer 60 is undoped and comprises GaN material.

A structured mask is applied to the surface of top layer 60 after the deposition of the various layers for preparation processing the optoelectronic device. As illustrated in FIG. 3B of the proposed method, the structured mask comprises mask elements 40 covering the surface of top layer 60. The top surface of layer 60 is exposed in portions 63 between the mask elements 40. The mask elements 40 also cover several dislocations on the top surface of layer 60, leaving the randomly located dislocations only in areas 63 exposed. Hence, those dislocations in the exposed areas are still accessible. Structured mask 40 is made of the hard mask. SiO₂ or any other dielectric material is suitable for forming such mask as it withstands the subsequent porosification process. Alternatively, the mask can also be made of photo resist or other material as long as the respective material withstands the subsequent porosification process.

As the positions of other dislocations on the exposed areas 63 of the surface of top layer 60 is random and also comprises a density of about 1e8 dislocations/cm², it is not necessary to take the position of the dislocations into account when structuring of the respective mask. Rather, the covered portions and the structured mask can be applied in any way suitable for subsequent deposition of the functional layer stack for an optoelectronic device for example.

Subsequently, an electrochemical prosecution process is applied on wafer level after the application of the structured mask. For this purpose, an etchant is applied to the top surface, particularly onto the exposed areas of the top surface layer 60. Due to the randomly located dislocations at the exposed portions, the etchant passes through the exposed portions of the top layer 60 and into the sacrificial layer 30. The actual electrochemical porosification process initially starts in the sacrificial layer 30 by porosifying certain areas directly below top layer 60. FIG. 3C illustrates the initial phase of the porosification process.

The porosification process can be partially controlled by adjusting various parameter, including but not limited to the etchant concentration, the voltage and the current applied to the wafer and the sacrificial layer 30. It has been surprisingly found that the porosification not only takes place along the dislocations through the sacrificial layer, that is mainly in the vertical (growth direction) but also laterally, and in particularly beneath the covered portions of the surface of top layer 60. In other words, the etchant porosifies the sacrificial layer vertically as well as laterally, until a continuous porosification layer 37 in the sacrificial layer 30 is reached.

The porosification process extends laterally and vertically through the sacrificial layer and stops particularly at the interfaces between the sacrificial layer and the initial undoped buffer 20 as well as the top layer 60, respectively. However, the etchant causes small holes and cavities 61 in the range of 10 nm to about 100 nm in the top layer 60 as illustrated in FIGS. 3C and 3D. The holes 61 are located at the respective dislocations at the surface of top layer 60 and can hardly be avoided during the porosification process. Consequently, the surface on the exposed portions of top layer 60 becomes uneven and rough making it more difficult to smoothen the surface using further buffer layers deposited on the surface.

However, any generation of holes is prevented below the covered portions of the surface leaving the dislocations intact. Consequently, after removal of the structured mask material, the previously covered portions comprise a smooth and un-disturbed top surface of layer 60, while in the exposed portions a plurality of holes and cavities 61 are generated having a density in the range of the dislocation density, resulting in an uneven surface of top layer portion 60 at the exposed areas.

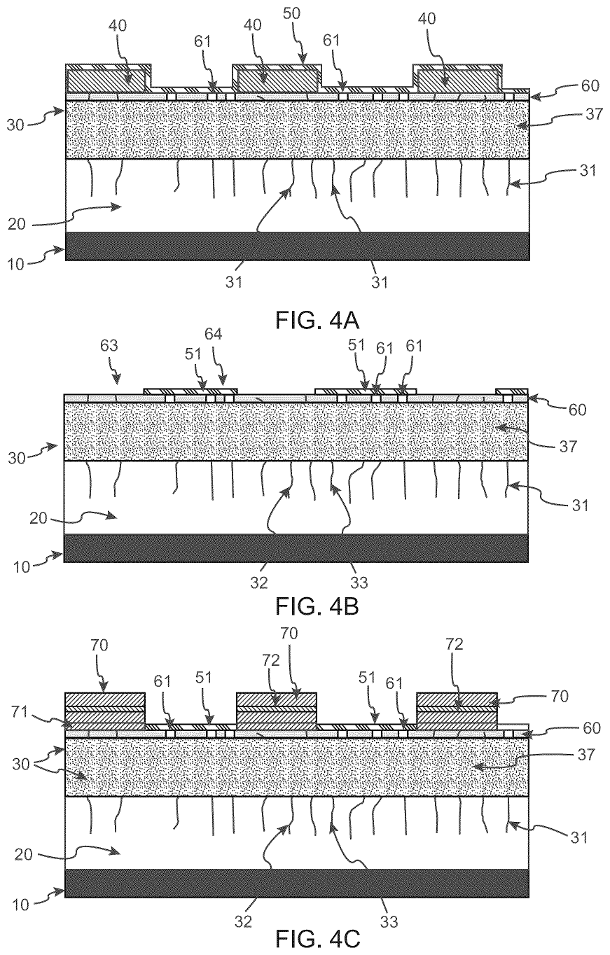

Various options for further processing of the device in accordance with the proposed principle are then possible, once the porosification process is finished and the etchant cleansed and removed. FIG. 4A to 4C illustrate a first embodiment of such additional structuring.

FIG. 4A illustrates a first step of such subsequent process, in which a dielectric mask 50 is applied on the surface of top layer 60 covering the holes in the exposed areas 61. As shown, the porosification process is finished having layer 60 completely porosified. In some aspects, the porosification may only be partially completed, such that smaller portion close to adjacent layers are still unporosified or less porosified. Even in such cases, the benefits of the present application are applied and in addition, the porosification process may be better controllable.

The dielectric mask 50 comprises SiO₂ and also can extend over the structured mask 40. It can also be deposited after removing the structured mask 40. Other materials for a dielectric mask can comprise suitable non-conductive materials and are also suitable. The material of the dielectric mask may in some aspect be selected so that it can be utilized later during the different processing steps. It may also be used as a protective cover for the underlying material.

The dielectric mask 50 covers the holes and cavities 61 created by the etchant on the previously exposed areas. It can comprise a thickness of tens or hundreds of nanometres to provide a more or less even surface on the previous exposed areas. However, as the previously exposed areas will not be overgrown, no high quality of the surface structure and roughness is required.

After the deposition of the dielectric material 50, the structured mask 40 is removed, leaving the previously covered areas 63 open and accessible to further processing steps. The dielectric material now covers the previously exposed portions 64. FIG. 4B illustrates the resulting layer structure. Although, the now exposed surface 63 may comprise randomly localized dislocations, the porosified sacrificial layer beneath reduces the strain significantly. Dielectric material 51 insulates the now exposed portions from each other. The thickness and height of the dielectric layer can be adjusted in the previous step enabling a proper isolation between the various exposed areas 63.

In further steps, a functional layer stack 70 is deposited on the now exposed portions 66, including one or more differently doped layers as well as an active region 72 in between. As particularly illustrated in FIG. 4C, the surface of top layer 60 is covered, for example, by a first doped Indium-Auminium-Gallium-Nitride layer InAlGaN, on which subsequently a layer stack including more heavily doped Indium-Aluminum-Gallium-Nitride, InAlGaN as well as an active region consisting of a multi-quantum well structure 72 consisting of Indium-Aluminum-Gallium-Nitride with different Aluminum and Indium contents are applied. The amount of Indium in this quaternary or ternary active region is used to adjust the wavelength with larger Indium content shifting the bandgap to smaller values, thus increasing the wavelength of photons. Likewise, a single active region or a single quantum well can be grown. In some instances, no Aluminum is used and the semiconductor material of the layer stack 70 is based on InGaN with different dopant and In concentrations.

Due to the Indium content in the functional layer stack 70, the stack comprises a lattice constant, which is different from the lattice constant of the initial buffer layer 20, as well as the sacrificial layer 30. However, due to the porosification process, porosified portion of sacrificial layer 30 now compensates the different lattice constant and the stress exerted thereupon. Consequently, Indium of the various contents can be introduced into the functional layer stack without compromising the quality of the stack.

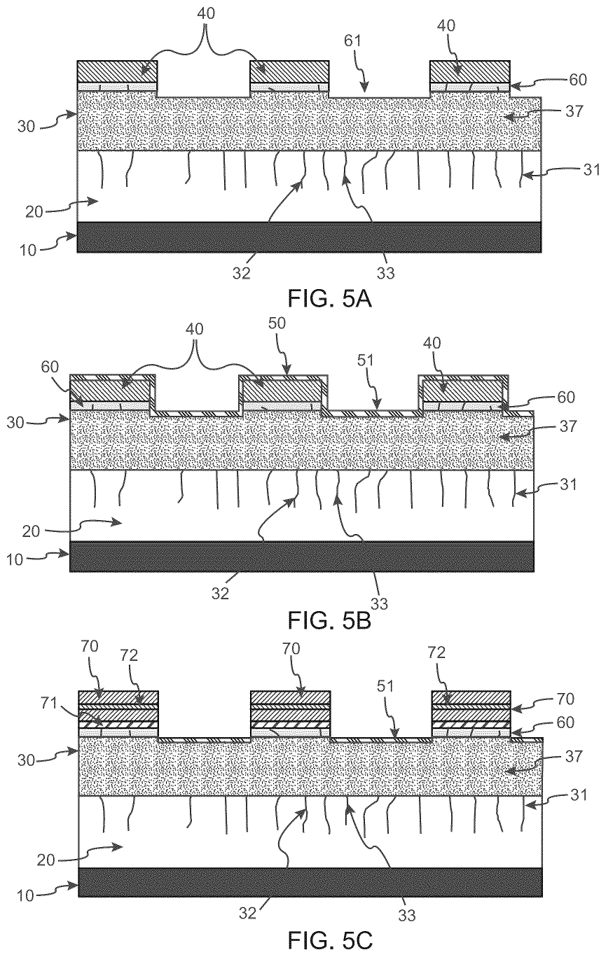

FIG. 5A to 5C illustrate a different exemplary embodiment in accordance with the proposed principles. The porosification process is similar, but additional processing steps are included in this example after the porosification process is completed.

In a first step, illustrated in FIG. 5A, the structured mask 40 already applied for the porosification process is now utilised for an additional etching process. The etching process removes the exposed portions of top layer 60 to form cavities 61 through the top layer 60 and into the porosified areas of sacrificial layer 30. The cavities 61 may reach through the top layer 60 into and past the porosified layer 37 depending on the respective needs and future process steps. In the present example, cavities 61 are formed slightly below the upper surface area of sacrificial layer 30 to ensure reaching the porosified layer material 37.

In a subsequent step, a dielectric material is isotropically deposited into cavities 61 as well as on the structured mask portions 40, but only partially on the sidewalls of the structured mask. The dielectric material 50 may include SiO₂ or any other suitable a dielectric material. The structured mask 40 is removed, exposing the previously covered surface of top layer 60.

A functional layer stack is subsequently generated on the exposed areas of top layer 60 including an Indium-based material similar to the previous processing method. For this purpose, the exposed surface with the dislocations are covered to with a first Indium-based material layer 71 (e.g. doped InGaN) for flattening and smoothing, and in particularly for covering and clearing the remaining dislocations on top layer 60. Due to the enhanced elastic properties, the porosified layer material 37 of sacrificial layer 30 compensates the strain induced by the growth of the indium-based material system.

After the functional layer stack has been generated, the device can be re-bonded, the initial growth substrate 10 and initial buffer 20 removed, until the sacrificial layer 30 is exposed. Depending on the respective application, the doped sacrificial layer 30 is utilized as a contact area for the respective functional layer stack. In addition, the respective functional layer stacks can be separated along the exposed areas. Other standard wafer fabrication steps can be utilized to obtain different configurations of devices such as volume emitting LEDs, upright LEDs (including micro LEDs) or thin film LEDs and micro LEDs.

Similarly, the dielectric material 51 separates the different layer stacks from each other. In addition, the porosified layer material 37 may also act as a diffusing material in applications, to enhance light outcoupling, in which the functional layer stack emits light through the respective material 37. Further to this embodiment, a converter material could be introduced into the porosified material 37 for converting the emitted light from the functional layer stack to a different wavelength. Such applications may be useful in cases, in which the functional layer stack is not already shifted to longer wavelengths by inducing Indium into the material system, but in which the functional layer is based on a Gallium-Nitride material having a wavelength in the blue or even ultraviolet range.

The present application and the proposed method utilises the fact that an etchant is able to diffuse through dislocations on a surface, thus reaching a sacrificial layer covered beneath. In addition, it has been found that, while a structured mask may cover dislocations in a top layer directly beneath, the etchant used for porosification is able to diffuse laterally beneath the covered areas to porosify sacrificial layer material. In other words, the etchant may reach a sacrificial layer through some dislocation on a top surface, porosifies the sacrificial layer laterally and vertically, but does not “move upwards” again through dislocations covered by mask material.

This effect actually allows providing a structured mask to cover dislocations, thereby avoiding the generation of small holes in the top layer, which are difficult to overgrow in later process steps, limiting and reducing the overall quality of the optoelectronic device. The covered areas in accordance with the present invention, however, provide a smooth and even surface, which is particularly suitable for the deposition of a respective material system including Indium for shifting the wavelength. The porosification degree and process can be controlled by various parameters. It is possible to adjust the porosification degree to accommodate the desired Indium content of the functional layer stack and thus the respective changes in the lattice constant.

1.-20. (canceled)

21. A method for processing an optoelectronic component having a semiconductor material including indium, the method comprising:
providing a growth substrate having a first lattice constant;
epitaxially depositing a sacrificial layer based on GaN with a dopant concentration higher than 1e¹⁸ atoms/cm³ having a second lattice constant different from the first lattice constant;
epitaxially depositing a top layer having a lower doping concentration than the sacrificial layer based on GaN having a third lattice constant different from the first lattice constant, wherein a growth of the sacrificial layer and the top layer generates a plurality of dislocations on a surface of the top layer;
providing a structured mask onto the surface of the top layer, wherein first portions of the surface are exposed and second portions of the surface are covered;
providing an etchant configured for electrochemical porosifying the sacrificial layer;
electrochemically porosifying the sacrificial layer through the dislocations on the exposed first portions such that the sacrificial layer below the second portions is at least partially porosified; and
forming a functional layer stack onto the second portions based on an InGaN semiconductor material, the functional layer stack comprising at least one active layer region.

22. The method according to claim 21, wherein electrochemical porosifying through the dislocations on the exposed first portions generates holes in the top layer, the holes having a diameter between 10 nm and 100 nm, inclusive.

23. The method according to claim 21, wherein the etchant porosifies the sacrificial layer laterally below the covered second portions.

24. The method according to claim 21, wherein the sacrificial layer comprises a porosification degree between 70% and 90%, inclusive.

25. The method according to claim 21, wherein the sacrificial layer and/or the top layer comprises at least one of GaN, GaP, AlGaN, InGaN, AlInGaN, AlInGaP or AlGaAs, and wherein the sacrificial layer is provided with a Si, Ge, Se, Sn, C, Zn, Be or Mg dopant during epitaxial deposition.

26. The method according to claim 21, wherein the top layer comprises an undoped layer or a layer having a dopant concentration which is at least 10 times lower than a dopant concentration in the sacrificial layer.

27. The method according to claim 21, wherein providing the growth substrate comprises epitaxial depositing a buffer layer based on GaN with a lattice constant that is different from the growth substrate or the sacrificial layer.

28. The method according to claim 21, wherein the dislocations are randomly located across the surface and comprise an average density in a range between 5e⁷ to 1e⁹ dislocations/cm².

29. The method according to claim 21, wherein the providing the structured mask comprises providing a dielectric mask onto the surface of the top layer.

30. The method according to claim 21, wherein forming the functional layer stack onto the second portions comprises depositing an n-type doped layer and a p-type doped layer with the least one active layer region in between.

31. The method according to claim 21, wherein forming the functional layer stack comprises:
removing the structured mask;
providing a dielectric layer on the first portions; and
forming a doped layer of InGaN based material on the second portions.

32. The method according to claim 21, wherein forming the functional layer stack comprises:
etching the first portions of the top layer at least till the porosified sacrificial layer forming a cavity;
depositing a dielectric layer into surface areas of the cavity; and
removing the structured mask.

33. The method according to claim 21, further comprising:
rebonding the functional layer stack; and
removing at least partially the sacrificial porosified layer.

34. The method according to claim 21, wherein the InGaN semiconductor material in the functional layer stack comprises In in a range between 0.0001% by mass to 25% by mass, inclusive.

35. The method according to claim 21, wherein the at least one active layer region comprises one or more quantum wells.

36. The method according to claim 21, wherein a lattice constant of at least one active layer region deviates from a lattice constant of the top layer in a range between 0.5% and 2.7%, inclusive.

37. An optoelectronic component comprising:
a growth substrate having an initial buffer layer;
a doped sacrificial layer arranged on the initial buffer layer;
an undoped top layer comprising first portions and second portions arranged on the doped sacrificial layer;
a functional layer stack based on InGaN semiconductor material located on the second portions, the functional layer stack comprising at least one active layer region; and
a dielectric layer arranged on the first portions,
wherein the doped sacrificial layer is porosified below the first and second portions.

38. The optoelectronic component according to claim 37, wherein randomly located dislocations in the second portions of the top layer have an average density in a range between 5e⁷ to 1e⁹ dislocations/cm², inclusive.

39. The optoelectronic component according to claim 37, wherein the sacrificial layer comprises a porosification degree larger than 30.

40. The optoelectronic component according to claim 37, wherein the InGaN semiconductor material in the functional layer stack comprises an indium content in a range between 0.0001% by mass to 25% by mass, inclusive.
